(19) United States
(12) Patent Application Publication
(10) Pub. No.: US 2009/0224356 A1
(43) Pub. Date: Sep. 10, 2009

(54) Method and apparatus for thermally aware design improvement

(76) Inventor: Rajit Chandra, Cupertino, CA (US)

Correspondence Address: WALSTEIN BENNETT SMITH III, P. O. BOX 1668, GEORGETOWN, TX, 78628, US

(21) Appl. No.: 11/317,664

(22) Filed: Dec. 23, 2005

Related U.S. Application Data
(63) Continuation-in-part of application No. 11/180,353, filed on Jul. 13, 2005, now Pat. No. 7,401,304.
Application No. 11/180,353 is a continuation-in-part of application No. 11/039,737, filed on Jan. 20, 2005, now Pat. No. 7,203,920.
Application No. 11/039,737 is a continuation-in-part of application No. 11/198,467, filed on Aug. 5, 2005, now Pat. No. 7,383,520.
Application No. 11/198,467 is a continuation-in-part of application No. 10/979,957, filed on Nov. 3, 2004, now Pat. No. 7,194,711.
Application No. 10/979,957 is a continuation-in-part of application No. 11/198,470, filed on Aug. 5, 2005, now Pat. No. 7,353,471.
Application No. 11/198,470 is a continuation-in-part of application No. 10/979,957, filed on Nov. 3, 2004, now Pat. No. 7,194,711.
Application No. 10/979,957 is a continuation-in-part of application No. 11/215,783, filed on Aug. 29, 2005, now Pat. No. 7,458,052.
Application No. 11/215,783 is a continuation-in-part of application No. 10/979,957, filed on Nov. 3, 2004, now Pat. No. 7,194,711.
Application No. 10/979,957 is a continuation-in-part of application No. 11/078,047, filed on Mar. 11, 2005, now Pat. No. 7,191,413.
Application No. 11/198,470 is a continuation-in-part of application No. 10/979,957, filed on Nov. 3, 2004, now Pat. No. 7,194,711.
Application No. 10/979,957 is a continuation-in-part of application No. 11/039,737, filed on Jan. 20, 2005, now Pat. No. 7,203,920.
Application No. 11/039,737 is a continuation-in-part of application No. 10/979,957, filed on Nov. 3, 2004, now Pat. No. 7,194,711.
Application No. 10/979,957 is a continuation-in-part of application No. 10/979,957, filed on Nov. 3, 2004, now Pat. No. 7,194,711.
(60) Provisional application No. 60/751,376, filed on Dec. 17, 2005.
(60) Provisional application No. 60/734,372, filed on Nov. 7, 2005.
(60) Provisional application No. 60/718,138, filed on Sep. 16, 2005.
(60) Provisional application No. 60/587,313, filed on Jul. 13, 2004.
(60) Provisional application No. 60/599,098, filed on Aug. 5, 2004.
(60) Provisional application No. 60/599,278, filed on Aug. 5, 2004.
(60) Provisional application No. 60/598,987, filed on Aug. 5, 2004.
(60) Provisional application No. 60/605,889, filed on Aug. 30, 2004.
(60) Provisional application No. 60/689,592, filed on Jun. 10, 2005.
(60) Provisional application No. 60/552,375, filed on Mar. 11, 2004.
(60) Provisional application No. 60/539,727, filed on Jan. 28, 2004.
(60) Provisional application No. 60/658,323, filed on Mar. 3, 2005.
(60) Provisional application No. 60/658,324, filed on Mar. 3, 2005.
(60) Provisional application No. 60/539,727, filed on Jan. 28, 2004.
(60) Provisional application No. 60/599,098, filed on Aug. 5, 2004.
(60) Provisional application No. 60/539,727, filed on Jan. 28, 2004.

(51) Int. Cl. H01L 25/00; G06F 17/50; G06F 19/00

(52) U.S. Cl. 257/499; 716/6; 257/678; 702/117; 257/E25.001

(57) ABSTRACT

Thermally aware design improvement enables increasing performance, reliability, and other related metrics by performing a multi-dimensional thermal analysis of a design of an electronic component in an assumed operating environment. Results of the analysis are then used to drive optimizations and repairs to the design. The performance metrics include maximum and minimum operating frequency, leakage current, power consumption, temperature gradient, absolute temperature, and other related parameters. The reliability metrics include Mean Time Between Failure (MTBF), required burn-in time, and other related parameters. In a related aspect, thermally aware design improvement enables performance driven electronic component design optimization and repair, including improving aspects of the physical design of an included semiconductor die. Improvements include modifying design details such as placement and routing of individual elements of the die. The thermal analysis and subsequent optimization and repair account for and attempt to mitigate the effects of temperature gradient induced problems.

### CROSS REFERENCE TO RELATED APPLICATIONS

Priority benefit claims for this application are made in the accompanying Application Data Sheet (if any). To the extent permitted by the type of the instant application, this application incorporates by reference for all purposes the following applications, which are all owned by the owner of the instant application:
U.S. application Ser. No. ______ (Docket No. GDA.2005.09NP) filed herewith, by Rajit Chandra, and entitled Method and Apparatus for Generating and Using Thermal Test Vectors;
U.S. application Ser. No. ______ (Docket No. GDA.2005.23NP) filed herewith, by Rajit Chandra, et al., and entitled Semiconductor Chip Design Having Thermal Awareness Across Multiple Sub-System Domains;
U.S. Provisional Application Ser. No. 60/751,376 (Docket No. GDA.2005.23) filed Dec. 17, 2005, by Rajit Chandra, et al., and entitled Semiconductor Chip Design Having Thermal Awareness Across Multiple Sub-System Domains;
U.S. Provisional Application Ser. No. 60/734,372 (Docket No. GDA.2005.24) filed Nov. 7, 2005, by Rajit Chandra, et al., and entitled Efficient Full-Chip Thermal Modeling and Analysis;
U.S. Provisional Application Ser. No. 60/718,138 (Docket No. GDA.2005.22) filed Sep. 16, 2005, by Rajit Chandra, and entitled Method and Apparatus for Temperature Assertion Based IC Design;
U.S. application Ser. No. 11/215,783 (Docket No. GRAD/011) filed Aug. 29, 2005, by Rajit Chandra, and entitled Method and Apparatus for Normalizing Thermal Gradients Over Semiconductor Chip Designs;
U.S. application Ser. No. 11/198,467 (Docket No. GRAD/009) filed Aug. 5, 2005, by Rajit Chandra, and entitled Method and Apparatus for Optimizing Thermal Management Systems Performance Using Full-Chip Thermal Analysis of Semiconductor Chip Designs;
U.S. application Ser. No. 11/198,470 (Docket No. GRAD/010) filed Aug. 5, 2005, by Rajit Chandra, and entitled Method and Apparatus for Using Full-Chip Thermal Analysis of Semiconductor Chip Designs to Compute Thermal Conductance;
U.S. application Ser. No. 11/180,353 (Docket No. GRAD/006) filed Jul. 13, 2005, by Ping Li, et al., and entitled Method and Apparatus for Thermal Modeling and Analysis of Semiconductor Chip Designs;
U.S. Provisional Application Ser. No. 60/689,592 (Docket No. GDA.2005.20) filed Jun. 10, 2005, by Rajit Chandra, and entitled Temperature-Aware Design Methodology;
U.S. application Ser. No. 11/078,047 (Docket No. GRAD/003) filed Mar. 11, 2005, by Rajit Chandra, et al., and entitled Method and Apparatus for Thermal Testing of Semiconductor Chip Designs;
U.S. Provisional Application Ser. No. 60/658,323 (Docket No. GDA.2005.09) filed Mar. 3, 2005, by Rajit Chandra, and entitled Method and Apparatus for Generating and Using Thermal Test Vectors;
U.S. Provisional Application Ser. No. 60/658,324 (Docket No. GDA.2005.08) filed Mar. 3, 2005, by Rajit Chandra, and entitled Method and Apparatus for Thermally Aware Design Improvement;
U.S. application Ser. No. 11/039,737 (Docket No. GRAD/007) filed Jan. 20, 2005, by Rajit Chandra, and entitled Method and Apparatus for Retrofitting Semiconductor Chip Performance Analysis Tools with Full-Chip Thermal Analysis Capabilities; and
U.S. application Ser. No. 10/979,957 (Docket No. GRAD/012) filed Nov. 3, 2004, by Rajit Chandra, and entitled Method and Apparatus for Full-Chip Thermal Analysis of Semiconductor Chip Designs.

### BACKGROUND

1. Field

Advancements in electronic component design are needed to provide improvements in performance, efficiency, and utility of use.

2. Related Art

Unless expressly identified as being publicly or well known, mention herein of techniques and concepts, including for context, definitions, or comparison purposes, should not be construed as an admission that such techniques and concepts are previously publicly known or otherwise part of the prior art. All references cited herein (if any), including patents, patent applications, and publications, are hereby incorporated by reference in their entireties, whether specifically incorporated or not, for all purposes. Nothing herein is to be construed as an admission that any of the references are pertinent prior art, nor does it constitute any admission as to the contents or date of actual publication of these documents.

### SUMMARY

The invention may be implemented in numerous ways, including as a process, an article of manufacture, an apparatus, a system, a composition of matter, and a computer readable medium such as a computer readable storage medium or a computer network wherein program instructions are sent over optical or electronic communication links. In this specification, these implementations, or any other form that the invention may take, may be referred to as techniques. In general, the order of the steps of disclosed processes may be altered within the scope of the invention. The Detailed Description provides an exposition of one or more embodiments of the invention that enable improvements in performance, efficiency, and utility of use in the field identified above. The Detailed Description includes an Introduction to facilitate the more rapid understanding of the remainder of the Detailed Description. The Introduction includes Illustrative Combinations that tersely summarize illustrative systems and methods in accordance with the concepts taught herein. As is discussed in more detail in the Conclusions, the invention encompasses all possible modifications and variations within the scope of the issued claims, which are appended to the very end of the issued patent.

Thermally aware design improvement enables increasing performance, reliability, and other related metrics by performing a multi-dimensional thermal analysis of a design of an electronic component in an assumed operating environment. Results of the analysis are then used to drive optimizations and repairs to the design. The performance metrics include maximum and minimum operating frequency, leakage current, power consumption, temperature gradient, absolute temperature, and other related parameters. The reliability metrics include Mean Time Between Failure (MTBF), required burn-in time, and other related parameters. In a related aspect, thermally aware design improvement enables performance driven electronic component design optimization and repair, including improving aspects of the physical design of an included semiconductor die. Improvements include modifying design details such as placement and routing of individual elements of the die. The thermal analysis and subsequent optimization and repair account for and attempt to mitigate the effects of temperature gradient induced problems.

### BRIEF DESCRIPTION OF DRAWINGS

Various embodiments of the invention are disclosed in the following detailed description and the accompanying drawings.

FIG. 1 illustrates an embodiment of a flow diagram for improving electronic component design by incorporating thermally aware analysis.

FIG. 2 illustrates an example of a hold time problem made apparent by thermally aware analysis.

FIG. 3A-C illustrate example repair techniques for the hold time problem of FIG. 2, as provided by thermally aware design improvement.

FIG. 4 illustrates an example of performance or reliability problems caused by high operational temperatures as recognized by thermally aware analysis.

FIGS. 5A-C illustrate example repair techniques for the performance and reliability problems of FIG. 4, as provided by thermally aware design improvement.

FIG. 6A illustrates an example of a noise problem brought about in part by a steep thermal gradient that is recognized by thermally aware analysis.

FIG. 6B illustrates an example improvement technique for the noise problem of FIG. 6A, as provided by thermally aware design improvement.

FIG. 7A illustrates an example of non-optimal driver placement as comprehended by thermally aware analysis.

FIG. 7B illustrates an example improvement technique for the non-optimal driver placement of FIG. 7A, as provided by thermally aware design improvement.

FIG. 8 illustrates an example of decreased reliability as detected by thermally aware analysis.

FIG. 9 illustrates an embodiment of a computer system for thermally aware design improvement.

### DETAILED DESCRIPTION

A detailed description of one or more embodiments of the invention is provided below along with accompanying figures that illustrate the principles of the invention. Some of the embodiments or variations thereof may be characterized as “notable.” The invention is described in connection with the embodiments, which are understood to be merely illustrative and not limiting. The invention is expressly not limited to or by any or all of the embodiments herein (notable or otherwise). The scope of the invention is limited only by the claims appended to the end of the issued patent and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

### Introduction

This introduction is included only to facilitate the more rapid understanding of the Detailed Description. The invention is not limited to the concepts presented in the introduction, as the paragraphs of any introduction are necessarily an abridged view of the entire subject and are not meant to be an exhaustive or restrictive description. For example, the introduction that follows provides overview information limited by space and organization to only certain embodiments. There are in fact many other embodiments, including those to which claims will ultimately be drawn, which are discussed throughout the balance of the specification.

Thermally aware design improvement enables increasing performance, reliability, and other related metrics by performing a multi-dimensional thermally aware analysis of a design of an electronic component in relation to an assumed operating environment. Results of the analysis are then used to drive optimizations and repairs to the design. The performance metrics include maximum and minimum operating frequency, leakage current, power consumption, temperature gradient, absolute temperature, and other related parameters. The reliability metrics include Mean Time Between Failure (MTBF), required burn-in time, and other related parameters.

In a related aspect, thermally aware design improvement enables performance driven electronic component design optimization and repair, including improving aspects of the physical design of an included semiconductor die. Improvements include modifying design details such as placement and routing of individual elements of the die. The thermal analysis and subsequent optimization and repair account for and attempt to mitigate the effects of temperature gradient induced problems. The problems include timing violations, reduced noise margins, current-resistance (IR) voltage drop, interconnect self-heating, leakage power increases, driver strength degradation, and analog circuit instability.

The thermal analysis includes analyzing a description of the design of the electronic component to determine a multi-dimensional temperature profile of operating temperatures throughout any portion of the electronic component, according to embodiment. The thermal analysis includes modeling and accounting for localized cooling structures and localized heating sources. Other analyses are performed using results of the thermal analysis, and include simulation (such as circuit, logic, and timing) and checking (such as timing, signal integrity and electrical rules), according to various embodiments. Thermal analysis and subsequent other analyses may be performed iteratively until desired closure between starting and final conditions is realized, according to various embodiments. Improvements are determined and specified by optimize and repair computations, and then provided to any combination of industry standard design automation tools, proprietary design automation tools, and customized design automation tools for implementation. Improvement specification and implementation may be performed iteratively until desired results are achieved, according to various embodiments. Any portion of computations relating to the aforementioned thermally aware analysis and improvement may be performed in a computer system including a computer readable medium storing program instructions relating to the computations.

The improvement techniques include reducing absolute temperature and decreasing thermal gradients, according to various embodiments. The embodiments include spreading apart elements operating at elevated temperatures, adding localized cooling structures in or near hot areas, and placing significant heat sources near existing elements that provide heat removal (such as package couplings including bond wire and solder bump sites). The improvement techniques further include decreasing thermal gradients by heating relatively cooler regions via adding localized heat generators (or sources) or locating relatively cool elements nearer relatively warmer elements, according to various embodiments.

The improvement techniques further include adding delay elements to increase propagation times (to repair hold time failures), and controlling placement of drivers and buffers to optimize or reduce delay times driving long wires, according to various embodiments. The improvement techniques further include altering power and ground routing on an integrated circuit die to reduce electromigration effects exacerbated by operation at higher temperatures, according to various embodiments. The improvement techniques further include reducing leakage current (and consequent heat generation), according to various embodiments. The embodiments include selective replacement of default threshold voltage (Vt) cells with higher Vt cells, according to various embodiments.

Vias may be introduced in one or more regions of an integrated circuit die for heat dissipation and temperature equalization benefits in such a manner that there is no change in the electrical connectivity and/or electrical/logical behavior of proximate circuitry. The term “mechanical via” is used herein to sometimes refer to such electrically inconsequential vias. In notable embodiments, mechanical vias are introduced that are directly or indirectly connected to parts of the package, particularly to the package ground interconnect (including, but not limited to wires and solder bumps). Mechanical vias may be introduced separately or as part of a thermal improvement process for purposes that include, but are not limited to, lowering temperature, lowering leakage current, and equalizing temperature across one or more regions of the die. In an example embodiment, a mechanical via is added as part of an improvement process to provide a heat conduction path from an otherwise high leakage current region to a ground pad landing site, or a ground bump site. By coupling the region to an effective heat dissipater, the operating temperature of the region is reduced, which in turn reduces the leakage current.

Localized cooling structures vary by embodiment and include sites for coupling between an integrated circuit die and a package (such as a bond-wire land and a solder-bump pad), and lead-frames. Other localized cooling structures include vias, stacked vias, mechanical vias, vias coupling to bond-wire land sites, vias coupling to solder-bump pads, metal islands or pools, and other similar elements having relatively high thermal conductivity and dissipation in a relatively low physical area or volume. Localized cooling may also be effected by proper relative alignment (or registration) of openings in generally coplanar metallization layers, according to implementation details.

Localized heat sources vary by embodiment and include elements generally having substantial power density, such as power diodes, power Field Effect Transistors (FETs), Direct Current (DC) voltage references, Input/Output (I/O) circuitry (dissipating switching and reference power), clock buffers, and low Vt logic gates. Other localized heat sources include interconnect such as individual and bussed signal wires, clock routes, and power and ground grids (sourcing Joule heating). Additional localized heat sources include passive elements such as resistors, capacitors, and inductors. Further localized heat sources include logic and memory elements having high leakage currents, portions of analog circuits (such as rectifiers and switches), and other similar elements having relatively high thermal energy generation in a relatively low physical area or volume.

The electronic component being thermally analyzed varies by embodiment and may be generally categorized as active or passive, and is often referred to as a “semiconductor chip” or simply a “chip” according to context. The electronic component is typically an integrated circuit and may optionally include a heatsink. The integrated circuit frequently includes at least one monolithic semiconductor die, a package for the die, and an attachment mechanism for coupling (electrically and mechanically) the die to the package. The thermal analysis accounts for thermal coupling and other effects between and including the die, the package, and the attachment.

The die may be formed from any number of various semiconductor technologies, according to embodiment, including Metal-Oxide Semiconductor (MOS), N-channel MOS (nMOS), P-channel MOS (pMOS), Complementary Metal-Oxide Semiconductor MOS (CMOS), Bipolar CMOS (BiCMOS), Gallium Arsenide (GaAs), and Bipolar. The die may include various types of operational circuitry, including any combination of analog circuitry, digital circuitry, and other similar circuitry, according to embodiment. The die may be considered to include various elements, the elements including devices (such as transistors, resistors, capacitors, diodes and inductors) and interconnect (such as wires, vias, and other elements providing electrical connectivity). The thermal analysis includes modeling thermal behaviors and properties associated with the die and the included elements.

The package may vary by embodiment, being any of a Dual Inline Package (DIP), a Quad Flat Pack (QFP), a Thin Slim-Outline Package (TSOP), a J-lead package, a Pin Grid Array (PGA), a Ball Grid Array (BGA), and any other similar packages. The package may be formed from organic, ceramic, or other suitable materials. The package may include pins, leads or pads for mounting to a socket or a Printed Circuit Board (PCB). The package may be compatible with surface mount and various mass board assembly techniques, such as a Tape Automated Bonding (TAB) compatible package and a Tape BGA (TBGA) package. The package may include an optional heat spreader, heatsink, or both. Related operating environmental factors may include any combination of a compatible socket and PCB. The thermal analysis recognizes various thermal properties and parameters of the package and the related operating environmental factors.

The die attachment mechanism may vary by embodiment, and may include Controlled Collapse Chip Connection (C4), thermal epoxy with wire bonding, and similar techniques. The thermal analysis includes modeling thermal behaviors and properties associated with the die attachment mechanism, including thermal interactions with the die and the package.

The optional heatsink may vary by embodiment, may be an active type or a passive type, and may include a heatpipe. The heatsink may be air or liquid cooled, and may be formed (by stamping or extruding, for example) from any combination of materials including copper, aluminum, and alloys thereof. The heatsink may be characterized by dimensions, mechanical fixtures (such as bonded-fins and folded-fins), and ducting configuration (such as fan-cooled with and without ducts). Related operating environmental factors may include ambient temperature and velocity. The thermal analysis provides for analyzing the thermal behavior of the heatsink, accounting for the various heatsink properties and related operating environmental factors.

### Design Improvement Flow

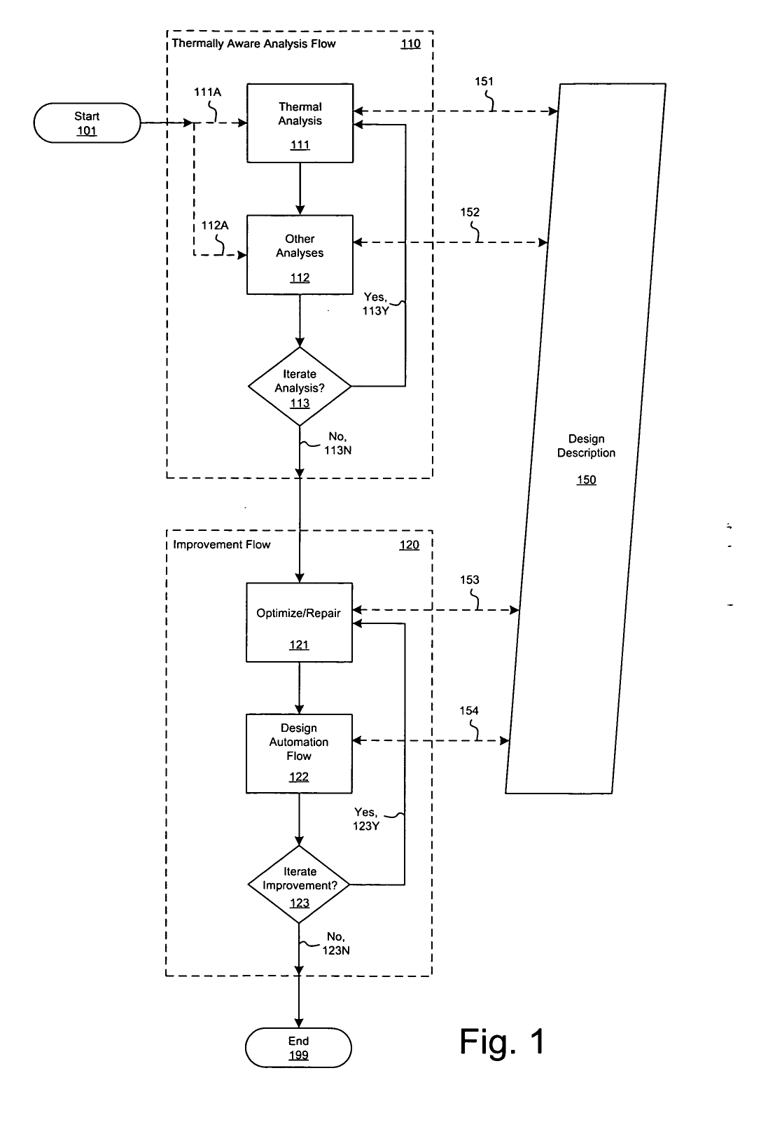

FIG. 1 illustrates an embodiment of a flow diagram for improving electronic component design by incorporating thermally aware analysis. As illustrated in the figure, the flow generally includes two phases. A first phase includes an iterative analysis of the electronic component accounting for thermal effects (“Thermally Aware Analysis Flow” 110). A second phase includes an iterative improvement of the design of the component (“Improvement Flow” 120), using information from the thermally aware analysis.

“Design Description” 150 is a collection of information defining various aspects of the particulars of the specifications for manufacturing and using the electronic component that is to be improved, including logical, physical, and mechanical descriptive data. Typically the electronic component is an integrated circuit that includes any combination of one or more monolithic die, a package for the die, an attachment mechanism to couple (electrically and mechanically) the die to the package, and heat dissipation elements. In some embodiments, the description is in the form of computer-readable files including any combination of a technology file, an extracted parasitic netlist file, timing constraints files, device and interconnect information files (such as geometry, orientation, and location information files), and average power files (from simulation or designer input). “Thermally Aware Analysis Flow” 110 and “Improvement Flow” 120, each with iterative processing, may optionally communicate information between each other and internal elements via the description, as illustrated conceptually by dashed-arrows 151-154, according to various embodiments.

More specifically as illustrated by the figure, flow beings (“Start” 101) and an analysis of the electronic component is performed, accounting for thermal properties and resultant behaviors (“Thermally Aware Analysis Flow” 110), with optional iterations. Results of the thermal analysis include expected operating temperatures (absolute or gradient) for various portions of the electronic component, including any combination of the die, the package, the die attach mechanism, and the optional heatsink.

Subsequently the electronic component design is improved (“Improvement Flow” 120), using information from the thermally aware analysis flow, also with optional iterations. Flow is then complete (“End” 199). The entire illustrated flow, from the start to the end may be repeated as desired, under the direct control of design personnel or programmatically, according to embodiment.

The thermally aware analysis flow begins by analyzing or simulating the thermal behavior of the electronic component design (“Thermal Analysis” 111), based in part on portions of “Design Description” 150. Output results include expected operating temperatures for various elements of the die, including various devices and interconnect. The results may also include a thermal diagram or temperature gradient map, indicating equi-thermal lines of identical temperature superimposed on a representation of the physical or mechanical layout of portions of the electronic component. Alternatively, a listing of elements and respective temperatures may be provided in a tabular format. Any combination of the results may be provided in human-readable and computer-readable representations.

Processing then proceeds with analyses according to procedures typically relying on the operating temperatures of the various elements as inputs (“Other Analyses” 112). In other words, the other analyses use temperature information provided by the thermal analysis to perform other operations, varying by embodiment and including circuit and logic simulation, as well as static timing analysis (STA). The other analyses further include signal integrity analyses, leakage current checking, and electrical rules checking. In some embodiments the circuit simulation is performed via any combination of industry standard tools such as SPICE, HSPICE, and HSIM. In some embodiments the logic simulation is performed via an industry standard Verilog compatible simulator. In some embodiments the STA is performed via an industry standard tool such as PrimeTime. Varying by embodiment, the signal integrity analyses include analyzing data signals, clock lines, and power grids, often using industry standard tools such as VoltageStorm and CeltIC. The electrical rules checking includes any combination of slew rate, current density, and electromigration checking, according to various embodiments.

After completing the other analyses, a determination is made as to whether additional thermal and other analyses are required (“Iterate Analysis” 113). If additional iterations are required (“Yes” 113Y), such as due to results of the other analyses indicating heat output from devices that is different than what was assumed prior to the thermal analysis, then flow returns to “Thermal Analysis” 111. If additional iterations are not required (“No” 113N), then the thermally aware analysis flow is complete, and flow continues, using the results of the analysis to improve the design (“Optimize/Repair” 121).

The optimize/repair processing examines the results of the thermal and other analyses to determine ways to improve the design of the electronic component. Improvements take the form of any combination of optimizations, repairs, and similar techniques to enable better performance of an instance of the electronic component manufactured according to portions of “Design Description” 150. Examples of selected improvement techniques are described elsewhere herein (see the “Example Improvement Techniques” section). Outputs of “Optimize/Repair” 121 include any combination of violation reports for inspection by design personnel, Engineering Change Order (ECO) scripts for input to design automation tools, and similar data for improving the design of the electronic component, according to various embodiments.

In some embodiments the ECOs are passed programmatically directly for use by “Design Automation Flow” 122. In some embodiments design personnel inspect the ECOs and selectively pass all or portions of them to the design automation flow. Typical implementations of the design automation flow include operation of one or more industry standard (or industry standard compatible) Computer Aided Design automation (CAD) tools using as input at least the ECOs and selected information from “Design Description” 150. The CAD tools typically include any combination of logic synthesizers, netlist generators, place and route tools, layout extractors, and other similar procedures to develop aspects of the physical implementation of the electronic component.

After completion of the design automation flow, a check is made to determine whether additional optimization/repair and design flow operations are necessary (“Iterate Improvement?” 123). If additional iterations are required (“Yes” 123Y), such as due to not meeting some of the optimize/repair specifications, then flow returns to “Optimize/Repair” 121. If additional iterations are not needed, then the improvement flow is complete, and flow continues via “No” 123N to “End” 199. In some embodiments checking for the need for additional operations (“Iterate Improvement?” 123) may be performed by design personnel, design programs, or both.

In some embodiments “Thermal Analysis” 111 provides thermal information to “Other Analyses” 112 via modifications to models referenced by the other analyses. For example, timing delay models used by an STA executed during the other analyses may be modified by the thermal analysis to reflect effects of operating temperatures (typically hotter devices operate longer propagation times while cooler devices operate with shorter propagation times). Similarly, power models read by a power grid analyzer may be modified according to results of the thermal analysis (typically hotter transistors have higher leakage currents and cooler transistors have lower leakage currents). As another example, interconnect properties used by an electromigration checking tool may be modified based on temperatures of operation of interconnects determined by the thermal analysis (higher temperatures generally being modeled as having greater susceptibility to electromigration effects).

In some embodiments “Thermal Analysis” 111 provides thermal information to “Other Analyses” 112 via differential (or incremental) parameter changes with respect to a fixed operating temperature point, conceptually similar to a “small-signal analysis” around the temperature point. Frequently implementations of elements of “Other Analyses” 112 (such as analyzers for timing, voltage drop, power, electromigration, and noise) perform an analysis at an assumed constant temperature (one of minimum, maximum, or nominal, for example). In other words, the analysis is performed as if all of the analyzed elements operated at the same temperature. However, results of the thermal analysis typically indicate operation of the analyzed elements at varying temperatures. In some of the fixed-temperature analysis implementation contexts “Thermal Analysis” 111 provides incremental data to facilitate a more accurate analysis that accounts for the determined temperature gradients.

Several illustrative examples serve to further describe the incremental analysis technique, as follows. The thermal analysis provides the timing analyzer with incremental delay information based on computed temperature variations. The incremental delays represent differences in propagation behavior between operation at the assumed temperature point and the temperature point determined by the thermal analysis. The voltage drop analyzer is provided with differential voltage drop information computed in accordance with the thermal analysis. The power analyzer is provided power variance information as relating to variation of leakage power with respect to the temperatures provided by the thermal analysis. The electromigration analyzer rule check is modified according to differences (above or below) assumed temperature operation of interconnect (signal, clock, supply, and so forth) according to thermal analysis results, including more stringent rules for elevated temperatures and correspondingly more relaxed rules for reduced temperatures. The noise analyzer is provided with information regarding signal waveform variation as a function of temperature according to the thermal analysis, the variation being obtained by a technique such as annotations of temperature variation in a circuit simulation.

In some embodiments portions of “Other Analyses” 112 may be incorporated into “Thermal Analysis” 111, optionally including iterations similar to “Iterate Analysis” 113. For example, an iterative logic/timing simulation may be performed that dynamically accounts for operating temperatures of various devices of the electronic component by accounting for localized heat generation due to dynamic switching activity. Similarly, a power grid analysis may be performed that feeds back power estimation information to an incorporated/integrated thermal analysis to determine new operating temperatures for devices. In turn thermal analysis results are input to a revised power grid analysis.

In some embodiments “Optimize/Repair” 121 relies on information from (“Other Analyses” 112. For example, an optimization or a repair may introduce a new timing problem or create a design rule violation. The optimize/repair processing selects a strategy based on any combination of the thermal analysis and the other analyses to avoid introducing new errors.

As illustrated, the thermally aware analysis is not restricted to beginning with a thermal analysis (dashed-arrow 111A). Instead processing may begin with other analyses (dashed-arrow 112A), under control of design personnel directives, programmatic selection, other determination schemes, or according to various embodiments. For example, in some embodiments it may be desirable to perform an initial logic simulation to determine activity factors (or fractional switching duty cycles) in preparation for the thermal analysis. The activity factors are used to provide information regarding heat source behavior, as transistors and interconnect (including resistive, capacitive, and inductive effects) typically dissipate more power (as heat) when changing state more often. For another example, in some embodiments it may be useful to perform an initial leakage analysis to estimate leakage power (having an exponential temperature dependence) in preparation for the thermal analysis. The leakage estimate is used to provide information regarding heating due to the elements dissipating the leakage power.

### Example Improvement Techniques

FIG. 2 illustrates an example of a hold time problem made apparent by thermally aware analysis (such as performed by “Thermally Aware Analysis Flow” 110 of FIG. 1). Cool Region 210 includes Source FFs 211, AND Gate 212, XNOR Gate 213, and AND Gate 214, all operating at a relatively low temperature, as determined by “Thermal Analysis” 111. Hot Region 220 includes Destination FF 221 and in close physical proximity, Heat Source 222, all operating at a relatively high temperature, as determined by “Thermal Analysis” 111. The elements of Cool Region 210 operate with relatively small delays, due at least in part to their relatively low operating temperature. Destination FF 221 operates with relatively large delays, due at least in part to its relatively high operating temperature, and the larger delays result in the FF requiring a relatively longer hold time to capture an input.

“Thermal Analysis” 111 provides the STA (typically performed as part of “Other Analyses” 112) with information describing the temperature affected relative timing performance between Cool Region 210 and Hot Region 220. The timing performance information may be explicit or implicit, according to embodiment. Explicit information typically takes the form of delay differentials or deltas, with respect to an assumed temperature operating point used by the STA. Implicit information is typically absolute or differential temperatures used by the STA to compute delay times accounting for temperature gradients. The STA recognizes that due to the relatively small delay of the path through Cool Region 210, in conjunction with the relatively longer hold time requirement of Destination FF 221, that there is a hold time problem in the path from Source FFs 211 to Destination FF 221. The detected hold time violation occurs under the conditions of the temperature gradient recognized by “Thermal Analysis” 111.

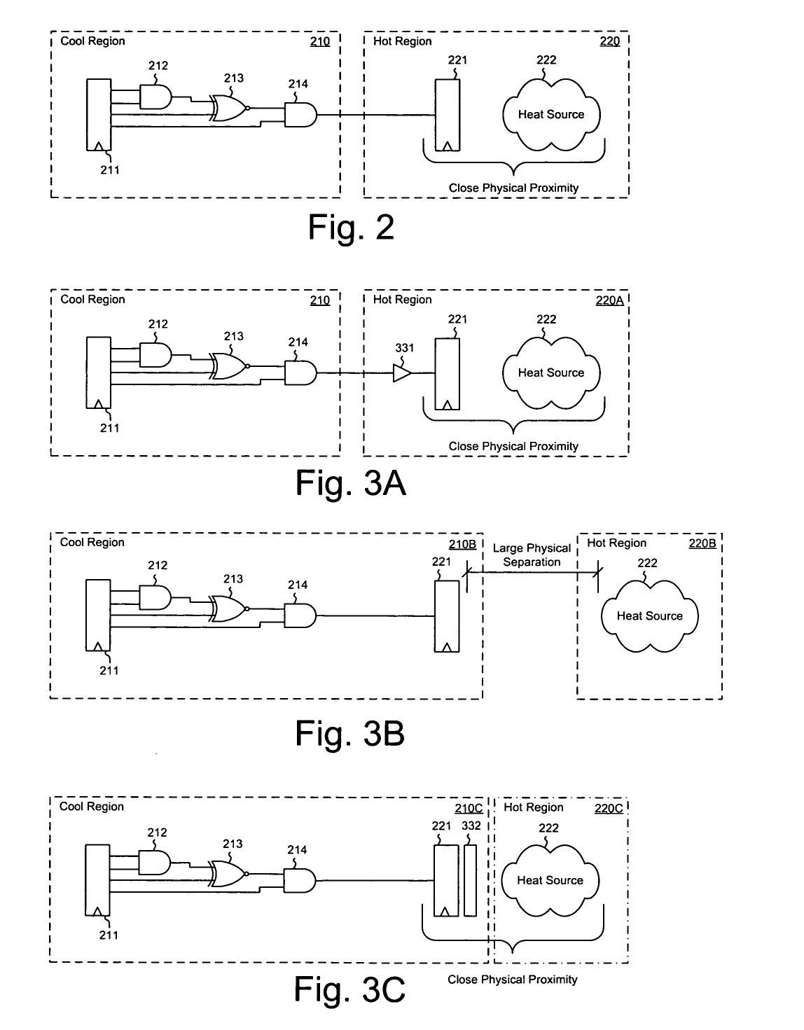

FIGS. 3A-C illustrate example repair techniques for the hold time problem of FIG. 2, as provided by thermally aware design improvement (such as performed by “Improvement Flow” 120 of FIG. 1). FIG. 3A illustrates adding propagation time in the hold time path, via insertion of Delay Element 331 coupling to the input of Destination FF 221, as a repair for the hold time violation. The elements of FIG. 3A are identical to those of FIG. 2, except for the addition of Delay Element 331. In the illustrated embodiment, the delay element is inserted into Hot Region 220A, where operation at a relatively higher temperature results in relatively longer propagation delays. In other embodiments the delay element may be inserted into Cool Region 210, as long as the delay element is chosen such that when it is operated at a relatively lower temperature, sufficient delay is added to the hold time path to prevent the hold time violation. Computations and determinations performed in “Optimize/Repair” 121 establish requirements for the delay element behavior while accounting for temperature effects, enabling proper selection and physical placement of the delay element.

FIG. 3B illustrates improving the hold time performance of Destination FF 221 by reducing its operating temperature via increased physical separation from Heat Source 222 as a repair for the hold time problem. The elements of FIG. 3B are identical to those of FIG. 2, except for the relative physical location of Destination FF 221 with respect to Heat Source 222. As illustrated, the region of relatively lower temperature operation (Cool Region 210B) extends to include Destination FF 221, due to increased separation from the heat source. The region of relatively higher temperature operation (Hot Region 220B) is correspondingly reduced in area. “Thermal Analysis” 111 identifies the heat source and “Optimize/Repair” 121 recognizes opportunity for improvement by decreasing the effect of the heat source on the FF by moving the elements further apart.

FIG. 3C also illustrates improving the hold time performance of Destination FF 221 by reducing its operating temperature as a repair for the hold time violation. However, in this example a heat removal element is added, via insertion of Cooling Structure 332, in close physical proximity to Destination FF 221. The elements of FIG. 3C are identical to those of FIG. 2, except for the addition of the cooling structure. As illustrated, the area of relatively lower temperature operation (Cool Region 210C) extends to include Destination FF 221, due to the addition of the cooling structure. The region of relatively higher temperature operation (Hot Region 220C) is correspondingly reduced in area. In this example, “Thermal Analysis” 111 identifies the heat source and “Optimize/Repair” 121 recognizes opportunity for improvement by decreasing the effect of the heat source on the FF by adding the heat removal element.

FIG. 4 illustrates an example of performance or reliability problems caused by high operational temperatures as recognized by thermally aware analysis (such as performed by “Thermally Aware Analysis Flow” 110 of FIG. 1). Hot Devices and Interconnect 410 includes Source FFs 411, XNOR Gate 412, NOR Gate 413, and Interconnect 414, in close physical proximity and all operating at a relatively high temperature, as determined by “Thermal Analysis” 111. The performance problems due to the elevated temperature may include increased leakage current (from the transistors in the FFs and Gates, for example), reduced current handling capability (in the interconnect, for example), or both. The reliability problems due to the higher temperature may include accelerated electromigration effects such as via damage and wire cracking, in any combination of the FFs, Gates, and interconnect.

In some embodiments “Thermal Analysis” 111 provides the electrical rules checking tool typically executed as part of “Other Analyses” 112 with temperature profile information for the elements of Hot Devices and Interconnect 410. The electrical rules checker recognizes the performance or reliability problems due to the high temperature operation. In some embodiments “Thermal Analysis” 111 provides the checking tools with modified rules that take into account operating temperatures of analyzed elements. For example, a rule for checking a power line routed near a large heat generator (and thus operating at a relatively higher temperature) may be made more stringent than a rule for checking a ground line routed far from heat generators (and thus operating at a relatively lower temperature).

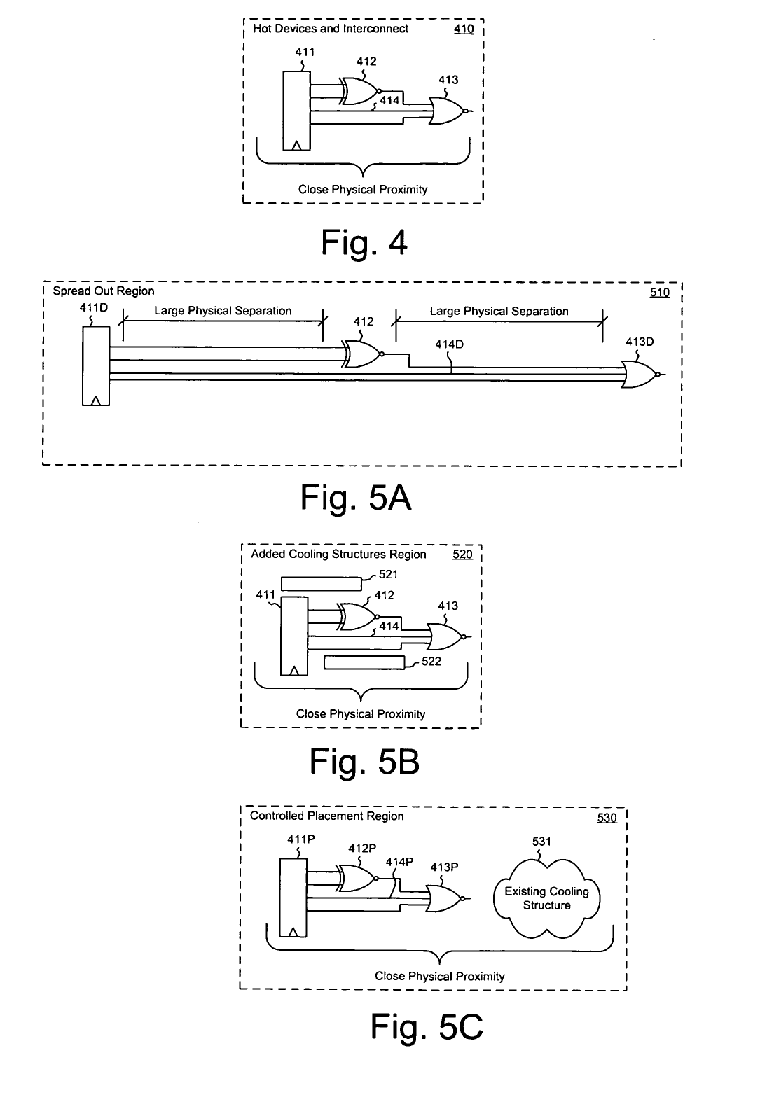

FIGS. 5A-C illustrate example repair techniques for the performance and reliability problems of FIG. 4, as provided by thermally aware design improvement (such as performed by “Improvement Flow” 120 of FIG. 1). FIG. 5A illustrates a first example for improving the performance and reliability of Hot Devices and Interconnect 410, by spreading out the elements of the hot region to decrease the peak temperature. As illustrated by Spread Out Region 510, using XNOR Gate 412 as a fixed physical reference point, Source FFs 411 and NOR Gate 413 are moved far away from XNOR Gate 412, as shown conceptually by Displaced Source FFs 411D and Displaced NOR Gate 413D, respectively. Separating the elements also lengthens Interconnect 414, as shown by relatively longer Displaced Interconnect 414D. Moving the elements apart and increasing the interconnect provides a larger area for heat dissipation, and therefore the highest temperature in the region decreases, reducing peak leakage current, increasing current capacity, and decreasing electromigration effects. Calculations carried out in “Optimize/Repair” 121 provide information regarding required additional separation to guide “Design Automation Flow” 122 to effect the performance and reliability improvement.

FIG. 5B illustrates a second example for improving the performance and reliability of Hot Devices and Interconnect 410 by insertion of cooling structures to reduce operating temperatures. The elements of FIG. 5B, as illustrated by Added Cooling Structures Region 520, are identical to those of FIG. 4 except for the addition of heat removal elements Cooling Structure 521 and Cooling Structure 522. The cooling structures decrease operating temperatures and thus effect improved performance and reliability, as in the previous example. Requirements on the nature and location of the heat removal elements are provided by “Optimize/Repair” 121 to “Design Automation Flow” 122 to implement improvements of an electronic component including functionality as specified by Hot Devices and Interconnect 410.

FIG. 5C illustrates a third example for improving the performance and reliability of Hot Devices and Interconnect 410 by guiding the physical location of the elements with respect to relatively efficient heat removal elements that are already present in the design of the electronic component. The elements of FIG. 5C, as illustrated by Controlled Placement Region 530, are substantially similar to those of FIG. 4 except that the FFs (Placed Source FFs 411P corresponding to Source FFs 411), Gates (Placed XNOR Gate 412P and Placed NOR Gate 413P corresponding respectively to XNOR Gate 412 and NOR Gate 413), and interconnect (Placed Interconnect 414P corresponding to Interconnect 414) have been placed near Existing Cooling Structure 531. Placement in close physical proximity to the existing heat removal element decreases operating temperatures and thus improves performance and reliability, as in the previous two examples. Requirements on the amount of cooling required to obtain the improvements are determined by “Optimize/Repair” 121. In some embodiments the optimize/repair processing also selects candidate existing cooling structures for identification to “Design Automation Flow” 122.

A fourth example for improving the performance and reliability of Hot Devices and Interconnect 410 includes replacing any combination of the FFs and Gates with higher Vt cells having equivalent logical functionality, thus reducing leakage current. Thermal profiles from “Thermal Analysis” 111 provided to leakage current computations typically performed in “Other Analyses” 112 enable recognition of an opportunity to decrease heat generation by reducing leakage current. “Optimize/Repair” 121 further analyzes the results and specifies cells for which to substitute higher Vt versions to “Design Automation Flow” 122.

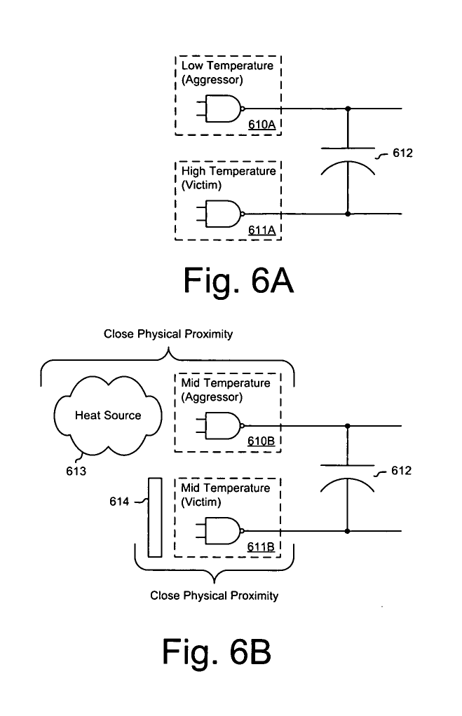

FIG. 6A illustrates an example of a noise problem brought about in part by a steep thermal gradient that is recognized by thermally aware analysis (such as performed by “Thermally Aware Analysis Flow” 110 of FIG. 1). Low Temperature (Aggressor) 610A affects High Temperature (Victim) 611A via Coupling Capacitance 612. In a failure mode, as the Victim output is being sampled by a storage element, the Aggressor switches at a high slew rate, coupling a transient to the Victim output and causing a sampling error. The error is magnified by the thermal gradient, as the Aggressor slews more quickly due to operation at a relatively low temperature, while the Victim recovery slew rate is slower due to operation at a relatively high temperature. In some embodiments temperature profiles, as determined by “Thermal Analysis” 111 and provided to the noise analysis performed by “Other Analyses” 112 enable detection of the noise problem. In some embodiments temperature aware noise behavior information is provided directly by the thermal analysis to the noise analysis.

FIG. 6B illustrates an example improvement technique for the noise problem of FIG. 6A, as provided by thermally aware design improvement (such as performed by “Improvement Flow” 120 of FIG. 1). Two mechanisms are illustrated, usable alone or in combination. A first mechanism includes addition of Heat Source 613 near the Aggressor, resulting in operation at a relatively higher temperature, as shown conceptually by Mid Temperature (Aggressor) 610B. A second mechanism includes addition of Cooling Structure 614 near the Victim, resulting in operation at a relatively lower temperature, as shown conceptually by Mid Temperature (Victim) 611B. The two techniques tend to reduce the thermal gradient (i.e. provide a more uniform temperature distribution) between the Aggressor and the Victim, thus reducing the relative affect of the Aggressor on the Victim, and the noise problem is mitigated, improving the design. Computations in “Optimize/Repair” 121 and corresponding results provided to “Design Automation Flow” 122 include any combination of heat source selection and placement, as well as cooling structure selection and placement, according to various embodiments.

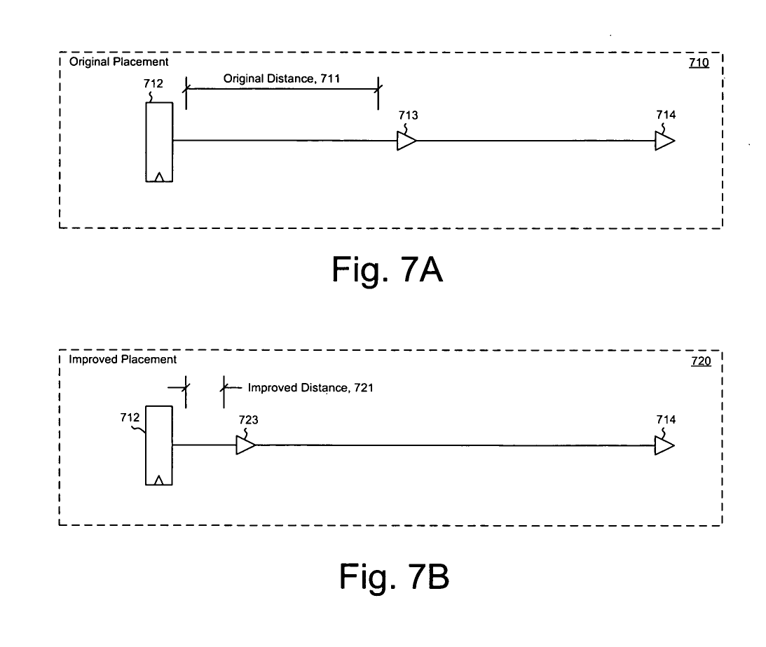

FIG. 7A illustrates an example of non-optimal driver (or buffer) placement as comprehended by thermally aware analysis (such as performed by “Thermally Aware Analysis Flow” 110 of FIG. 1). Original Placement 710 illustrates Source FF 712 coupling to Driver 713 placed at Original Distance 711 from the source, and in turn coupled to Receiver 714. In some embodiments temperature gradients determined by “Thermal Analysis” 111 are input to “Other Analyses” 112, and a determination is made that delay from the source to the receiver is longer than optimal. In some embodiments delay changes with respect to delays at an assumed temperature are provided directly from the thermal analysis to the other analyses.

FIG. 7B illustrates an example improvement technique for the non-optimal driver placement of FIG. 7A, as provided by thermally aware design improvement (such as performed by “Improvement Flow” 120 of FIG. 1). Improved Placement 720 illustrates replacement of Driver 713 by Improved Driver 723, in the context of the circuit illustrated in FIG. 7A. Improved Driver 723 is placed at a different location (relative to the source and the receiver) than the original driver, as indicated conceptually by Improved Distance 721. The improved placement is determined by operations performed in “Optimize/Repair” 121, and implemented by portions of “Design Automation Flow” 122. Although the figure illustrates a reduction in distance between the source and the driver, in some circumstances the distance may instead be increased. Further, some embodiments use any combination of improved placement and improved driver sizing (or driver strength selection) to improve driver implementation.

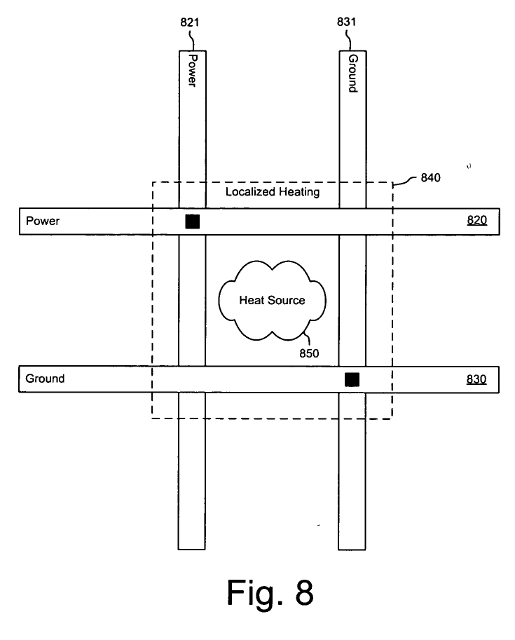

FIG. 8 illustrates an example of decreased reliability as detected by thermally aware analysis (such as performed by “Thermally Aware Analysis Flow” 110 of FIG. 1). The figure illustrates a portion of a vertical view of selected metallization and related features of an integrated circuit layout. An excerpt of power and ground grids (also known collectively as supply grids) for the circuit is shown (Horizontal Power Rail 820, Horizontal Ground Rail 830, Vertical Power Rail 821, and Vertical Ground Rail 831). The circuit includes an area of substantial power consumption, shown as Heat Source 850, resulting in increased temperatures in Localized Heating Area 840.

Decreased reliability in the locally heated region (due to increased temperature of operation) is detected by the electrical rules checking typically performed in “Other Analyses” 112 based, in some embodiments, on temperature profile information provided by “Thermal Analysis” 111. In some embodiments the thermal analysis provides modified rules for checking, with the modified rules accounting for the determined temperature gradients. Typically the modified rules specify reductions in projected reliability as temperature increases above a reference temperature normally used by the checking, and increases in reliability as the temperature decreases below the reference temperature.

In some embodiments, “Optimize/Repair” 121 provides an ECO to “Design Automation Flow” 122 to improve the reliability by modifying the supply grid. The ECO specifies any combination of increased supply routing widths, additional supply metal layers, added supply straps and routes, implemented within or physically near Localized Heating Area 840. The ECO is based in part on temperature information provided by “Thermal Analysis” 111. In some embodiments ECOs are generated that improve reliability by reducing maximum temperature (i.e. decreasing thermal gradients) caused by the heat source. The thermal profile smoothing ECOs specify any combination of adding heat removal structures, spreading out the heat source, and other similar changes.

In typical scenarios, the horizontal routes are on a first metal layer while the vertical routes are on a second metal layer, with each of the metal layers being a different distance from an underlying (and generally coplanar) substrate (not shown in the figure). The substrate is often an effective heat dissipater, and in some embodiments “Thermal Analysis” 111 computes thermal profiles in three dimensions (including distance from the substrate) to account for cooling provided by the substrate. Thus the aforementioned ECOs may specify different routing width changes, for example, for vertical versus horizontal traces (even when the traces are of the same material and properties), based on temperature differentials between the vertical and horizontal traces due to corresponding differences in distance from the substrate. Similarly, the electrical rules checking typically performed in “Other Analyses” 112 may optionally include temperature aware current density rules.

FIG. 8 also illustrates an example of reduced performance as determined by thermally aware analysis (such as performed by “Thermally Aware Analysis Flow” 110 of FIG. 1). Increased electrical resistance, and hence increased IR induced voltage drops, are detected by the voltage drop checking typically performed in “Other Analyses” 112 based, in some embodiments, on temperature profile information provided by “Thermal Analysis” 111. In some embodiments the thermal analysis provides modified rules accounting for the determined temperature gradients.

In some embodiments, “Optimize/Repair” 121 provides an ECO to “Design Automation Flow” 122 to improve the performance by modifying the supply grid, similar to the improvements for reliability. In some embodiments the ECO may specify addition of cooling structures or modified placement of the heat source or the supply grid. The ECO is based in part on temperature information provided by “Thermal Analysis” 111. Those of ordinary skill in the art will recognize applicability of voltage drop repairs to interconnect of other types, such as individual signals, busses, and clock lines, in addition to supply lines.

### Design Improvement System

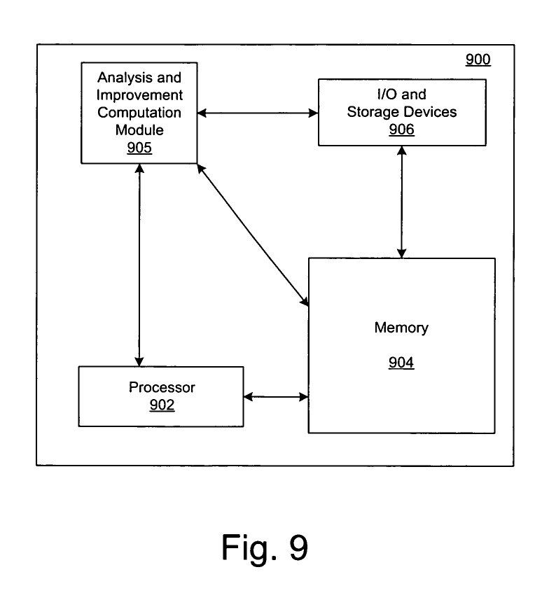

FIG. 9 illustrates an embodiment of a Computer System 900 for thermally aware design improvement. The Computer System is a general purpose computing system such as a Personal Computer (PC), Workstation, or Server, and includes a Processor 902, a Memory 904, an Analysis and Improvement Computation Module 905 and various Input/Output (I/O) and Storage Devices 906. In some embodiments any combination of the aforementioned procedures or portions thereof (such as “Thermally Aware Analysis Flow” 110 and “Improvement Flow” 120) are implemented via Analysis and Improvement Computation Module 905. The I/O and Storage Devices module includes any combination of a display, a keyboard, a mouse, a modem, a network connection, a magnetic disk drive, an optical disk drive, and similar devices. In some embodiments the storage devices store all or portions of “Design Description” 150.

In some embodiments Analysis and Improvement Computation Module 905 is implemented as a physical device or subsystem that is coupled to a processor through a communication channel. Alternatively, the module may be implemented by one or more software applications (or even a combination of software and hardware, e.g., using Application Specific Integrated Circuits (ASIC)), where the software is loaded from a storage medium (such as from I/O and Storage Devices 906) and operated by Processor 902 in Memory 904 of Computer System 900. Additionally, the software may run in a distributed or partitioned fashion on two or more computing devices similar to Computer System 900. Thus, in some embodiments, Analysis and Improvement Computation Module 905 for computations relating to thermally aware electronic component design improvement, described herein with reference to the preceding figures, can be stored on a computer readable medium or carrier (e.g., RAM, magnetic or optical drive or diskette, and similar storage media).

### CONCLUSION

Although the foregoing embodiments have been described in some detail for purposes of clarity of understanding, the invention is not limited to the details provided. There are many ways of implementing the invention. The disclosed embodiments are illustrative and not restrictive.

It will be understood that many variations in construction, arrangement and use are possible consistent with the teachings and within the scope of the claims appended to the issued patent. For example, interconnect and function-unit bit-widths, clock speeds, and the type of technology used may generally be varied in each component block. The names given to interconnect and logic are merely illustrative, and should not be construed as limiting the concepts taught. The order and arrangement of flowchart and flow diagram process, action, and function elements may generally be varied. Also, unless specifically stated to the contrary, the value ranges specified, the maximum and minimum values used, or other particular specifications (such as specific semiconductor technology), are merely those of the illustrative embodiments, may be expected to track improvements and changes in implementation technology, and should not be construed as limitations.

Functionally equivalent techniques known to those of ordinary skill in the art may be employed instead of those illustrated to implement various components, sub-systems, functions, operations, routines, and sub-routines. It is also understood that many design functional aspects may be carried out in either hardware (i.e., generally dedicated circuitry) or software (i.e., via some manner of programmed controller or processor), as a function of implementation dependent design constraints and the technology trends of faster processing (which facilitates migration of functions previously in hardware into software) and higher integration density (which facilitates migration of functions previously in software into hardware). Specific variations may include, but are not limited to: hardware acceleration of thermal analysis and optimization/repair; and other variations to be expected when implementing the concepts taught herein in accordance with the unique engineering and business constraints of a particular application.

The embodiments have been illustrated with detail and environmental context well beyond that required for a minimal implementation of many of aspects of the concepts taught. Those of ordinary skill in the art will recognize that variations may omit disclosed components or features without altering the basic cooperation among the remaining elements. It is thus understood that much of the details disclosed are not required to implement various aspects of the concepts taught. To the extent that the remaining elements are distinguishable from the prior art, components and features that may be so omitted are not limiting on the concepts taught herein.

All such variations in design comprise insubstantial changes over the teachings conveyed by the illustrative embodiments. It is also understood that the concepts taught herein have broad applicability to other computing and networking applications, and are not limited to the particular application or industry of the illustrated embodiments. The invention is thus to be construed as including all possible modifications and variations encompassed within the scope of the claims appended to the issued patent.

What is claimed is:

1. A method including the steps of:
performing a thermally aware analysis of an electronic component design; and
improving the electronic component design as a function of the thermally aware analysis.

2. The method of claim 1, wherein the thermally aware analysis produces a temperature profile.

3. The method of claim 2, wherein the temperature profile includes a multi-dimensional temperature profile.

4. The method of claim 3, wherein the multi-dimensional temperature profile includes a three-dimensional profile.

5. The method of claim 1, wherein the thermally aware analysis includes a thermal simulation.

6. The method of claim 1, wherein the thermally aware analysis includes a static timing analysis.

7. The method of claim 6, wherein the static timing analysis is a function of a temperature-dependent model.

8. The method of claim 7, wherein the temperature-dependent model is dependent on the thermally aware analysis.

9. The method of claim 1, wherein the thermally aware analysis includes a voltage drop analysis.

10. The method of claim 9, wherein the voltage drop analysis is a function of a temperature-dependent model.

11. The method of claim 10, wherein the temperature-dependent model is dependent on the thermally aware analysis.

12. The method of claim 1, wherein the electronic component design improvement includes an optimization.

13. The method of claim 1, wherein the electronic component design improvement includes a repair.

14. The method of claim 1, wherein the electronic component design improvement includes an engineering change order.

15. The method of claim 14, wherein the engineering change order is readable by an industry standard electronic component design tool.

16. The method of claim 15, wherein the industry standard electronic component design tool includes one or more of:
an integrated circuit floorplanning tool;
an integrated circuit placement tool; and
an integrated circuit routing tool.

17. A method including the steps of:
simulating thermal behavior of an electronic component design;
evaluating the electronic component design in accordance with the thermal behavior simulating; and
improving the electronic component design based on at least one of the thermal behavior simulating and the evaluating.

18. The method of claim 17, wherein the thermal behavior simulating includes generating a temperature profile.

19. The method of claim 18, wherein the temperature profile is in two dimensions.

20. The method of claim 18, wherein the temperature profile is in three dimensions.

21. The method of claim 17, wherein the thermal behavior simulating includes effects of localized thermal structures.

22. The method of claim 21, wherein the localized thermal structures include localized cooling structures.

23. The method of claim 21, wherein the localized thermal structures include localized heating structures.

24. The method of claim 17, wherein the evaluating includes at least one of
a circuit simulation;
a logic simulation;
a timing simulation;
a static timing evaluation;
a signal integrity evaluation;
a power evaluation;
a voltage drop evaluation;
a reliability evaluation;
an electromigration evaluation;
a leakage current evaluation;
an electrical rules evaluation; and
a design rule evaluation.

25. A method including the steps of:
developing a multi-dimensional thermal profile corresponding to an integrated circuit design;
assessing the integrated circuit design in accordance with the thermal profile; and
enhancing the integrated circuit design based on at least one of the thermal profile and the assessing.

26. The method of claim 25, wherein the enhancing includes fixing a violation.

27. The method of claim 26, wherein the assessing includes checking to determine the violation.

28. The method of claim 27, wherein the checking includes at least one of
a static timing checking;
a signal integrity checking;
a leakage current checking;
a power checking;
a voltage drop checking;
a reliability checking;
an electromigration checking;
an electrical rules checking; and
a design rule checking.

29. The method of claim 25, wherein the integrated circuit design includes at least one of
a semiconductor die design;
a package design; and
a specification describing a die-to-package attachment.

30. The method of claim 29, wherein the semiconductor die design is compatible with a semiconductor technology including at least one of
a metal-oxide semiconductor technology;
an N-channel metal-oxide semiconductor technology;
a P-channel metal-oxide semiconductor technology;
a complementary metal-oxide semiconductor technology;
a silicon-on-insulator semiconductor technology;
a silicon-germanium semiconductor technology;
a bipolar complementary metal-oxide semiconductor technology;
a gallium arsenide semiconductor technology; and
a bipolar semiconductor technology.

31. The method of claim 29, wherein the package design is compatible with at least one of
a dual Inline package;
a quad flat pack package;
a thin slim-outline package;
a J-lead package;
a pin grid array package;
a ball grid array package;
an organic package;
a ceramic package;
a through-hole mount package;
a surface mount package; and
a tape automated bonding package.

32. The method of claim 29, wherein the package design specifies inclusion of at least one of
an integral heat spreader;
an integral thermal slug;
an integral heatsink; and
an integral heatpipe.

33. The method of claim 25, wherein:
the integrated circuit design includes a package design; and
the thermal profile is developed in accordance with the package design.

34. The method of claim 33, wherein:
the package design specifies a heat dissipation element; and
the thermal profile is developed in accordance with parameters associated with the heat dissipation element.

35. The method of claim 34, wherein the heat dissipation element is at least one of
a heat spreader;
a thermal slug;
a heatsink; and
a heatpipe.

36. The method of claim 33, wherein:
the package design is compatible with mounting on a printed circuit board; and
the thermal profile is developed in accordance with parameters associated with the printed circuit board.

37. The method of claim 33, wherein:
the package design is compatible with mounting in a socket; and
the thermal profile is developed in accordance with parameters associated with the socket.

38. A monolithic integrated circuit including:
a heat generating element and a heat dissipating element; and
wherein the integrated circuit is built according to a design description;
wherein the design description includes layout data specifying relative physical placement of the heat dissipating element with respect to the heat generating element; and
wherein the relative physical placement is determined in part by a thermally aware analysis of the design description.

39. The method of claim 38, wherein the thermally aware analysis includes a multi-dimensional thermally aware analysis.

40. The method of claim 38, wherein the multi-dimensional thermally aware analysis includes a three-dimensional thermally aware analysis.

41. The monolithic integrated circuit of claim 38, wherein the heat generating element includes at least one of
a transistor;
a diode;
a resistor;
a capacitor;
an inductor; and
a wire.

42. The monolithic integrated circuit of claim 38, wherein the heat dissipating element includes at least one of
a bond-wire land;
a solder-bump pad;
a via;
a stacked via;
a mechanical via;
a via coupled to a bond-wire land site;
a via coupled to a solder-bump pad; and
an area of metallization.

43. The monolithic integrated circuit of claim 38, wherein the thermally aware analysis includes calculating an expected thermal gradient as a function of at least a portion of the design description.

44. The monolithic integrated circuit of claim 38, wherein a mask to manufacture the integrated circuit is developed in part from information included in the design description.

45. The monolithic integrated circuit of claim 38, wherein the design description includes information describing at least one of the heat generating element and the heat dissipating element.

46. The monolithic integrated circuit of claim 45, wherein the information describing the at least one of the heat generating element and the heat dissipating element is provided to the thermally aware analysis.

47. The monolithic integrated circuit of claim 38, further including analog circuitry.

48. The monolithic integrated circuit of claim 38, further including digital circuitry.

49. The monolithic integrated circuit of claim 38, wherein the relative physical placement is determined in part by a design automation tool.

50. The monolithic integrated circuit of claim 49, wherein the design automation tool is responsive to thermal analysis data provided by the thermally aware analysis.

51. The monolithic integrated circuit of claim 50, wherein the thermal analysis data includes an operating temperature of at least one of the heat generating element and the heat dissipating element.

52. The monolithic integrated circuit of claim 50, wherein the thermal analysis data includes a performance parameter derived with respect to an operating temperature of at least one of the heat generating element and the heat dissipating element.

53. The monolithic integrated circuit of claim 52, wherein the performance parameter is an operating-temperature-adjusted parameter.

54. The monolithic integrated circuit of claim 53, wherein the operating temperature-adjusted parameter is at least one of
a propagation delay;
a signal noise value;
a leakage current value;
a threshold voltage value;
a slew rate; and
a current density value.

55. The monolithic integrated circuit of claim 52, wherein the performance parameter is an operating-temperature-differential parameter.

56. The monolithic integrated circuit of claim 55, wherein the operating-temperature-differential parameter is mathematically combined with a corresponding base-temperature parameter.

57. The monolithic integrated circuit of claim 55, wherein a mathematically combination of the operating-temperature-differential parameter and a corresponding base-temperature parameter is at least one of
a propagation delay;
a signal noise value;
a leakage current value;
a threshold voltage value;
a slew rate; and
a current density value.

58. The monolithic integrated circuit of claim 50, wherein the thermal analysis data includes a rule checking value derived with respect to an operating temperature of at least one of the heat generating element and the heat dissipating element.

59. The monolithic integrated circuit of claim 58, wherein the rule checking value is an operating-temperature-adjusted value.

60. The monolithic integrated circuit of claim 59, wherein the operating-temperature-adjusted value is at least one of
a maximum propagation delay;
a minimum propagation delay;
a maximum signal noise value;
a maximum leakage current value;
a maximum threshold voltage value;
a minimum threshold voltage value;
a maximum slew rate;
a minimum slew rate;
a maximum current density value; and
a minimum current density value.

61. The monolithic integrated circuit of claim 58, wherein the rule checking value is a temperature-dependent adjustment value.

62. The monolithic integrated circuit of claim 61, wherein the temperature-dependent adjustment value is added with a corresponding assumed-temperature base value.

63. The monolithic integrated circuit of claim 62, wherein the corresponding assumed-temperature base value is at least one of
a nominal value;
a minimal value; and
a maximal value.

64. The monolithic integrated circuit of claim 61, wherein the temperature-dependent adjustment value is at least one of
a propagation delay increase;
a propagation delay decrease;
a signal noise value increase;
a signal noise value decrease;
a leakage current value increase;
a leakage current value decrease;
a threshold voltage value increase;
a threshold voltage value decrease;
a slew rate increase;
a slew rate decrease;
a current density value increase; and
a current density value decrease.

65. The monolithic integrated circuit of claim 38, wherein the integrated circuit is compatible with mounting in a package.

66. The monolithic integrated circuit of claim 38, wherein the integrated circuit is compatible with a controlled collapse chip connection (C4) package attachment technique.

67. The monolithic integrated circuit of claim 38, wherein the integrated circuit is compatible with a wire-bond package attachment technique.

68. An electronic component including:
a package including at least a first region of relatively high heat dissipation capacity;
a monolithic semiconductor circuit mounted to the package, the semiconductor circuit having at least a second region adapted to operate at a relatively high power density;
within the semiconductor circuit at least one interconnect instance adapted to thermally couple the at least first region to the at least second region; and
wherein the at least one interconnect instance is otherwise electrically inconsequential.

69. The electronic component of claim 68, wherein the at least one electrically inconsequential interconnect instance includes at least one of:
a via;
a minimum unit of metal fill;
a solder bump; and
a bond wire.

70. The electronic component of claim 68, wherein the package includes ground interconnect and the at least one electrically inconsequential interconnect includes at least one via connected to the package ground interconnect.

71. The electronic component of claim 68, wherein physical placement of the at least one electrically inconsequential interconnect is determined at least in part on a thermally driven performance improvement of the component.

72. The electronic component of claim 71, wherein the thermally driven performance improvement of the component includes a thermally aware analysis of the component.

73. The electronic component of claim 72, wherein the thermally aware analysis of the component generates a temperature profile.

74. The electronic component of claim 73, wherein the temperature profile includes an operating temperature for at least one of the regions.

75. The electronic component of claim 72, wherein the thermally aware analysis of the component is based at least in part on one of
a thermal property of the first region;
a thermal property of the second region;
the power density of the second region; and
a thermal property of the package;

76. The electronic component of claim 68, wherein the at least one electrically inconsequential interconnect lowers an average operating temperature of the component.

77. The electronic component of claim 76, wherein an average leakage current of the component is reduced by the at least one electrically inconsequential interconnect.

78. The electronic component of claim 68, wherein the at least one electrically inconsequential interconnect lowers a maximum operating temperature of the component.

79. The electronic component of claim 78, wherein a maximum leakage current of the component is reduced by the at least one electrically inconsequential interconnect.

80. The electronic component of claim 68, wherein the at least one electrically inconsequential interconnect reduces an average temperature gradient of the component.

81. The electronic component of claim 68, wherein the at least one electrically inconsequential interconnect reduces a maximum temperature gradient of the component.

82. A system including:
an integrated circuit die;
an integrated circuit package;
an attachment mechanism attaching the package with the integrated circuit die; and
wherein the die is developed with a temperature-aware design flow.

83. The system of claim 82, wherein the temperature-aware design flow includes at least one of
a selectively performed repair process;
a temperature-gradient-aware static timing checking;
a temperature-gradient-aware signal integrity checking;
a temperature-gradient-aware threshold voltage checking;
a temperature-gradient-aware voltage drop checking;
a temperature-gradient-aware reliability checking;
a temperature-gradient-aware electromigration checking;
a temperature-gradient-aware leakage current checking; and
a temperature-gradient-aware electrical rules checking.

84. The system of claim 83, wherein the temperature-gradient-aware static timing checking includes checking timing performance of first and second regions of the integrated circuit die according to concurrent operation at respective first and second operating temperatures.

85. The system of claim 84, wherein the first region includes at least one of
a single passive element;
a single active element;
a plurality of passive elements;
a plurality of active elements;
a combination of active and passive elements;
a logic gate;
a logic storage circuit;
a memory array;
an interconnect;
a plurality of interconnects;
a combination of logic gates and interconnects; and
an analog circuit.

86. The system of claim 85, wherein the second region includes at least one of
a single passive element;
a single active element;
a plurality of passive elements;
a plurality of active elements;
a combination of active and passive elements;
a logic gate;
a logic storage circuit;
a memory array;
an interconnect;
a plurality of interconnects;
a combination of logic gates and interconnects; and
an analog circuit.

87. The system of claim 83, wherein the temperature-gradient-aware signal integrity checking includes checking signal integrity of first and second regions of the integrated circuit die according to concurrent operation at respective first and second operating temperatures.

88. The system of claim 83, wherein the temperature-gradient-aware leakage current checking includes checking leakage current of first and second regions of the integrated circuit die according to concurrent operation at respective first and second operating temperatures.

89. The system of claim 83, wherein the temperature-gradient-aware electrical rules checking includes checking electrical rules of first and second regions of the integrated circuit die according to concurrent operation at respective first and second operating temperatures.

90. The system of claim 82, wherein the integrated circuit die is implemented with at least one of
a metal-oxide semiconductor technology;
an N-channel metal-oxide semiconductor technology;
a P-channel metal-oxide semiconductor technology;
a complementary metal-oxide semiconductor technology;
a bipolar complementary metal-oxide semiconductor technology;
a silicon-on-insulator technology;
a silicon-germanium semiconductor technology;
a gallium arsenide semiconductor technology; and
a bipolar semiconductor technology.

91. The system of claim 82, wherein the package includes at least one of
a heat spreader;
a thermal slug;
a heatsink; and
a heatpipe.

92. A system including:
an input/output device to receive a description of an electronic component;
a processor to execute computer programs;
a computer readable medium to store the computer programs, the computer programs being adapted to execute functions including
thermal analysis of the description of the electronic component, and
enhancement of an operating characteristic of the electronic component according to the thermal analysis.

93. The system of claim 92, wherein the enhancement includes a determination of respective temperature operating points for a plurality of elements of the electronic component.

94. The system of claim 93, wherein the enhancement includes an analysis of performance of the elements according to the temperature operating points.

95. The system of claim 94, wherein the enhancement includes identification of an improvement according to the analysis of performance.

96. The system of claim 95, wherein the identification of the improvement is further according to the thermal analysis.

97. The system of claim 96, wherein the analysis of performance includes at least one of
a circuit simulation;
a logic simulation;
a timing simulation;
a static timing evaluation;
a signal integrity evaluation;
a leakage current evaluation;
a threshold voltage evaluation;
an electrical rules evaluation; and
a layout design rule evaluation.

98. The system of claim 92, wherein the enhancement is according to thermal operating data provided by the thermal analysis, the thermal operating data including at least one of
a temperature profile of elements of the electronic component;
a two-dimensional temperature profile of elements of the electronic component;
a three-dimensional temperature profile of elements of the electronic component;
temperature gradient information of elements of the electronic component;
two-dimensional temperature gradient information of elements of the electronic component;
three-dimensional temperature gradient information of elements of the electronic component; and
temperatures of operation of at least two elements of the electronic component.

99. The system of claim 92, wherein the enhancement is according to a thermally-corrected operating characteristic provided by the thermal analysis, the thermally-corrected operating characteristic including at least one of
a delay characteristic;
a noise characteristic;
a leakage characteristic;
a slew characteristic; and
a current density characteristic.

100. The system of claim 92, wherein the enhancement is according to a thermally-derived adjustment provided by the thermal analysis, the thermally-derived adjustment including at least one of
a delay characteristic increase;
a delay characteristic decrease;
a noise characteristic increase;
a noise characteristic decrease;
a leakage characteristic increase;
a leakage characteristic decrease;
a slew characteristic increase;
a slew characteristic decrease;
a current density characteristic increase; and
a current density characteristic decrease.

101. The system of claim 92, wherein the enhancement is according to a thermally-corrected limit provided by the thermal analysis, the thermally-corrected limit including at least one of
a maximum delay limit;
a minimum delay limit;
a maximum noise limit;
a maximum leakage current limit;
a maximum slew rate limit;
a minimum slew rate limit; and
a maximum current density limit.

102. The system of claim 92, wherein the enhancement is according to a thermally-derived adjustment provided by the thermal analysis, the thermally-derived adjustment including at least one of
an adjustment to a maximum delay limit;
an adjustment to a minimum delay limit;
an adjustment to a maximum noise limit;
an adjustment to a maximum leakage current limit;
an adjustment to a maximum slew rate limit;
an adjustment to a minimum slew rate limit; and
an adjustment to a maximum current density limit.

103. A computer readable medium containing an executable program to perform thermally aware electronic component design modifications, wherein the program performs the steps of:
analyzing thermal behavior of an electronic component according to a corresponding design;
modifying the design;
coupling results of the analyzing to the modifying.

104. The computer readable medium of claim 103, wherein the computer program further performs the step of coupling results of the modifying to the analyzing.

105. The computer readable medium of claim 103, wherein the computer program further performs the step of verifying the design.

106. The computer readable medium of claim 105, wherein the verifying includes at least one of
a static timing verification;
a signal integrity verification;
a leakage current verification;
an electrical rules verification; and
a layout verification.

107. The computer readable medium of claim 105, wherein the modifying is responsive to the verifying.

108. The computer readable medium of claim 107, wherein the modifying includes repairing an error detected by the verifying.

109. The computer readable medium of claim 107, wherein the modifying includes improving a metric estimated by the verifying.

110. The computer readable medium of claim 109, wherein the metric includes at least one of
a cycle time;
a hold time margin;
a noise margin;
a leakage current;
a maximum current density;
a maximum temperature;
an average temperature;
a maximum temperature gradient; and
an average temperature gradient.

111. The computer readable medium of claim 107, wherein the modifying includes optimizing a metric determined by the verifying.
